(19) United States
(12) Patent Application Publication
(10) Pub. No.: US 2012/0177945 A1
(43) Pub. Date: Jul. 12, 2012

(54) Whisker-Free Coating Structure and Method for Fabricating the Same

(75) Inventors: Yee-Wen Yen, Taipei (TW); Jinn P. Chu, Taipei (TW); Chon-Hsin Lin, Taipei (TW); Chun-Lei Hsu, Taipei (TW); Chao-Kang Li, Taipei (TW)

(73) Assignee: National Taiwan University of Science and Technology, Taipei (TW)

(21) Appl. No.: 13/415,842

(22) Filed: Mar. 9, 2012

Related U.S. Application Data
(63) Continuation-in-part of application No. 12/471,162, filed on May 22, 2009, now abandoned.

(51) Int. Cl. B32B 15/00; C23C 28/02; B32B 15/01; C23C 14/35; B82Y 30/00; B82Y 40/00

(52) U.S. Cl. 428/641; 428/646; 204/192.15; 205/186; 977/755

(57) ABSTRACT

The present invention relates to a whisker-free coating structure and a method for fabricating the same. The whisker-free coating structure comprises a substrate, a tungsten doped copper layer and a lead-free tin layer, wherein the tungsten doped copper layer and the lead-free tin layer are formed on the substrate in turns; So that, the whisker growth in the lead-free tin layers can be effectively suppressed by this whisker-free coating structure.

### CROSS-REFERENCE TO RELATED APPLICATION

This application is a continuation-in-part of co-pending U.S. patent application Ser. No. 12/471,162 for the same title filed on May 22, 2009, the content of which is hereby incorporated by reference in its entirety.

### BACKGROUND OF THE INVENTION

1. Technical Field

The present invention relates to a lead-free solder technology, and more particularly, to a whisker-free coating structure and method for fabricating the same.

2. Description of Related Art

Copper with high electrical conductivity are typically utilized as a main lead-frame material in electronic products using surface mount technology (SMT) for assembly. Further, copper is also widely utilized in printed circuit boards as a substrate and wiring material. In some applications, copper substrates, wiring terminals or lead-frame surfaces are covered by tin-lead or solder alloys utilizing electroplating or hot dip coating for enhancing wetting abilities between the copper substrates, wirings or leads and solders, to improve the bonding abilities there between.

Conventionally, the solder materials covering the copper substrates, wiring terminals or lead-frame surfaces are mainly a eutectic tin-lead (Sn-37Pb) alloy. Metal lead, however, is a heavy metal that not only pollutes the environment, but also negatively affects human health. As such, countries like the European Union (EU) has adopted standards such as the Waste Electrical and Electronic Equipment Directive (WEEE) and the Restriction of certain Hazardous Substances Directive (RoHS) that limit metal lead compositions in electronic products. Thus, lead-containing materials for electrical and electronic products are being replaced by lead-free materials. Therefore, it is necessary for domestic and international electronic product manufactures to replace conventional lead-containing assembly processes with lead-free assembly processes.

Conventional leaded devices mostly utilize copper or iron-nickel alloy materials. In lead-containing assembly processes, device leads are plated and covered by tin-lead alloys.

In lead-free assembly processes, structures are replaced by copper lines or leads with high electrical conductivity covered by lead-free solders. Lead-free solder materials mostly utilize pure tin or tin-0.7 wt % copper alloy systems. While more environmentally friendly however, lead-free solder materials do have characteristic problems. Specifically, at room temperature, idiopathic tin whiskers growth occurs on the surfaces of lead-free solder materials. When the tin whiskers grow close to neighboring device leads, point discharge occurs thereto due to the high electric field, and sparks occur which may cause fires or device failure. When the tin whiskers grow close to neighboring device leads and are long enough to contact the leads, short circuiting may occur.

Tin whiskers are mainly formed by compressive stress which is caused by diffusion between a tin layer and a copper substrate, wherein intermetallic compounds are formed. The diffusion normally occurs along grain boundaries of the tin layer due to the higher diffusion coefficient of the tin atoms located thereat. The tin atoms flow along the direction of the compressive stress and pass through the surface of the oxide layer of the tin layer for tin whiskers to grow.

In order to solve the whiskers, package venders propose a new flip-chip bonding technology. Please refer to FIG. 1, there is shown a side view of a chip and a lead-frame used in a new flip-chip bonding technology. As shown in FIG. 1, when applying the new flip-chip bonding technology, via bond pads 12′ are formed on the surface of a chip 10′, wherein the via bond pad 12′ includes multi-layer structure, consisting of: a first metallization layer 11′, a diffusion layer 14′, a sputtered copper layer 16′, a second metallization layer 18′, and a flip-chip bump 20′. In the via bond pad 12′, the material of the first metallization layer 11′ may be Al, Al/Cu alloy (Al/2% Cu), or Al/Si/Cu alloy (Al/1% Si/0.5% Cu), the material of the diffusion layer 14′ is Ti/W alloy, the material of the second metallization layer 18′ may be Cu, Al or Ni, and the material of the flip-chip bump 20′ is Zn. In addition, a gold layer (not shown) is formed on the surface of the flip-chip bump 20′ for being a protection layer.

In FIG. 1, numeric 26′ indicates a lead-frame. The lead-frame 26′ has a plurality of bond pads 22′, and each bond pad's 22′ surface is formed with a Sn layer 24′ used for enhancing wetting ability of the bond pad 22′. Therefore, to joint the chip 10′ with the lead-frame 26′, the chip 10′ is disposed onto the lead-frame 26′ for making the via bond pad 12′ of the chip 10′ contact with the bond pads 22′ of the lead-frame 26′. Then, an energy source will be provided to bring the temperature for the contact area to 240-290° C., and the via bond pad 12′ would joint with bond pads 22′ without occurring any whiskers.

By above descriptions for the new flip-chip bonding technology, the person skilled in the art is able to, indeed, know that the new flip-chip bonding technology can prevent the occurrence of the whiskers when the flip-chip bonding is executed; However, when practice the new flip-chip bonding technology, the person skilled in the art also found the new technology includes the drawbacks and shortcomings as follows:

1. When using the new flip-chip bonding technology, the via bond pad 12′ with multi-layer structure needs to be fabricated. However, making via bond pad 12′ with multi-layer structure would increase the manufacturing coast of the chip 10′, moreover, it may cause damages on the chip 10′ during the processing.

2. The new flip-chip bonding technology is greatly different from the conventional flip-chip bonding technology, such that the conventional package venders doesn't want to apply the new flip-chip bonding technology, and the chip manufactures are unwilling to fabricate the via bond pad 12′ with multi-layer structure.

Accordingly, in view of the new flip-chip bonding technology cannot entirely solve the problems occurring in conventional soldering materials and flip-chip bonding technologies; the inventor of the present application has made great efforts to make inventive research thereon and eventually provided a whisker-free coating structure and method for fabricating the same.

### BRIEF SUMMARY OF THE INVENTION

The first objective of the present invention is to provide a whisker-free coating structure, comprising a substrate, a tungsten doped copper layer, and a lead-free tin layer; So that, the whisker growth in the lead-free tin layers can be effectively suppressed by this whisker-free coating structure.

Accordingly, for achieving first objective of the present invention, the inventor proposes a whisker-free coating structure, comprising:

a substrate;

a tungsten doped copper layer, being formed on the substrate; and

a lead-free tin layer, being formed on the tungsten doped copper layer;

wherein the tungsten doped copper layer has the tungsten atoms of 0.3-8.2 atom percent, and the lead-free tin layer has the tin atoms of at least 95 atom percent.

Moreover, for achieving first objective of the present invention, the inventor further proposes a method for fabricating a whisker-free coating structure, comprising:

providing a substrate;

forming a tungsten doped copper layer on the substrate by way of a vacuum magnetron sputtering apparatus, wherein the tungsten doped copper layer has the tungsten atoms of 0.3-8.2 atom percent; and

forming a lead-free tin layer on the tungsten doped copper layer, wherein the lead-free tin layer has the tin atoms of at least 95 atom percent.

### BRIEF DESCRIPTION OF THE SEVERAL VIEWS OF THE DRAWINGS

The invention as well as a preferred mode of use and advantages thereof will be best understood by referring to the following detailed description of an illustrative embodiment in conjunction with the accompanying drawings, wherein:

FIG. 1 is a side view of a chip and a lead-frame used in a new flip-chip bonding technology;

FIG. 2 is a side-sectional view of a whisker-free coating structure according to the present invention;

FIG. 3A and 3B are secondary-electron image photographs of the whisker-free coating structure;

FIG. 4A and 4B are secondary-electron image photographs of the whisker-free coating structure; and

FIG. 5 is a schematic framework view of a magnetron sputtering equipment used for forming a tungsten doped copper layer of the whisker-free coating structure.

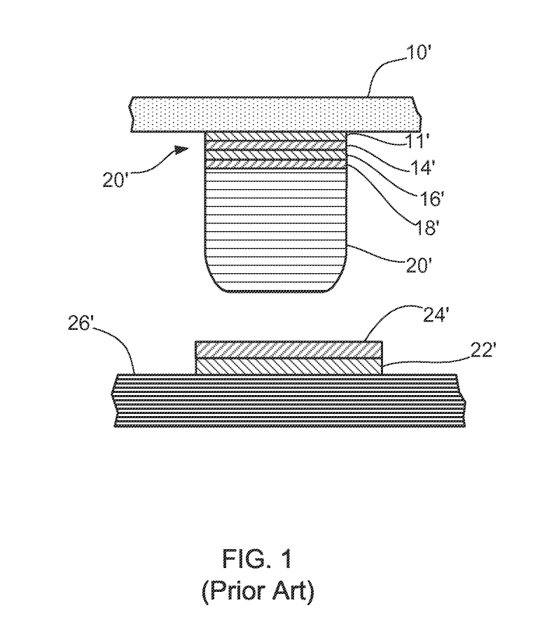

### DETAILED DESCRIPTION OF THE INVENTION

To more clearly describe a whisker-free coating structure and a method for fabricating the whisker-free coating structure according to the present invention, embodiments of the present invention will be described in detail with reference to the attached drawings hereinafter.

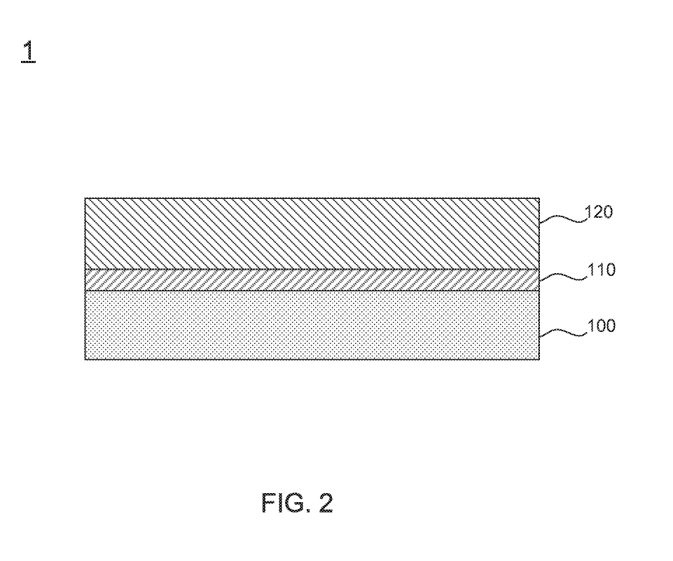

Please refer to FIG. 2, which illustrates a side-sectional view of a whisker-free coating structure according to the present invention. As shown in FIG. 2, the whisker-free coating structure 1 includes: a substrate 100, a tungsten doped copper layer 110 and a lead-free tin layer 120, wherein the tungsten doped copper layer 110 and the lead-free tin layer 120 are formed on the substrate 100 in turns. In the present invention, particularly, the tungsten doped copper layer has the tungsten atoms of 0.3-8.2 atom percent and the lead-free tin layer has the tin atoms of at least 95 atom percent. Moreover, it is noted that, preferably, in the present invention, the tungsten doped copper layer has the tungsten atoms of 0.3-0.6 atom percent.

The substrate 100 can be a silicon substrate, a copper foil substrate, or a lead-frame; moreover, the silicon substrate can be a silicon wafer, an epitaxial layer overlaying a silicon wafer, a silicon-on-insulator (SOI) layer overlaying a silicon wafer, a thin film transistor silicon layer overlaying a silicon wafer, or the like. Alternatively, the substrate 100 may be formed by other semiconductor materials. The copper foil substrate can be an electrodeposited copper foil (ED foil) or a rolled annealed copper foil (RA foil) formed by cold work, such as rolling, and annealing. Moreover, the lead-frame can be a lead-frame for common lead packages or quad flat non-lead (QFN) packages.

For the tungsten doped copper layer 110, tungsten and copper can be considered as mutually insoluble metals, such that the tungsten doped copper layer 110 is formed by co-sputtering to dope tungsten into the copper. In the present invention, the tungsten doped copper layer has the tungsten atoms of 0.3-8.2 atom percent. When the atom percentage of the tungsten in the tungsten doped copper layer 110 is lower than 0.3 atom percent, the effect suppressing the whisker growth in the tin layer overlaying the tungsten doped copper layer 110 is limited. Besides, when the atom percentage of the tungsten in the tungsten doped copper layer 110 is higher than 8.2 atom percent, the electrical resistivity value of the tungsten doped copper layer 110 is increased, such that the advantages of utilizing copper as the conductive layer may be hindered or limited.

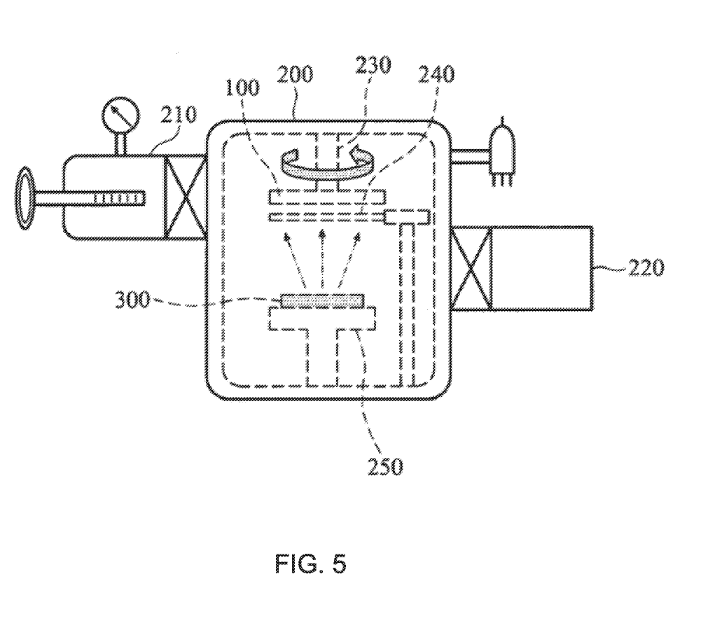

The tungsten doped copper layer 110 is formed by a magnetron sputter deposition process performing co-sputtering of tungsten and copper. Please Refer to FIG. 5, there is shown a schematic framework view of a magnetron sputtering equipment used for forming a tungsten doped copper layer of the whisker-free coating structure. As shown in FIG. 5, an appropriate surface cleaning process can be performed on the substrate 100, followed by placing the substrate 100 in a spin table 230 in a chamber 200 of a magnetron sputtering equipment via a load region 210. At this time, a target 300 is provided overlaying a target pedestal 250 in the chamber 200. Further, a mask layer may be preformed overlaying the substrate 100 when utilizing the lift-off to form the patterned tungsten doped copper layer 110.

Inheriting to above descriptions, next, gas in the chamber 200 is exhausted by a turbo pump 220 until the air pressure (vacuity) in the chamber 200 is below 7×10⁻³ torr, and then high pure argon is introduced into the chamber 200. Then, a co-sputtering process is performed under a pressure of between 10⁻³ torr and 10⁻² torr. Particles sputtered from the target 300 hit and attach to the substrate 100. The thickness of the tungsten doped copper layer 110 can be controlled by the sputtering period determined by the open and close switching of a shutter 240, and be formed on the substrate 100 with thickness ranged from 2 nm to 500 nm. For control of tungsten concentrations in the tungsten doped copper layer 110, reference may be made to the deposition conditions between a pure copper target and a tungsten target disclosed by Taiwan patent publication No. 00574431 (hereafter referred as TW 574431). For other sputtering conditions, reference may be made to Table 2 in TW 574431 or Table 2 in Taiwan patent issue No. 1237328 (hereafter referred as TW 1237328).

After the co-sputtering process for formation of the tungsten doped copper layer 110 is completed, an annealing process can be optionally performed as required, and the annealing conditions can follow the conditions disclosed in pages 5 and 6 of “descriptions of the invention” of TW574431. Further, when a functional pattern such as a wiring pattern or the like is required, the tungsten doped copper layer 110 can be patterned by a lift-off, lithography, or the like process.

Moreover, for the lead-free tin layer 120, which can be a matte tin layer of pure tin formed by electroplating, overlaying the tungsten doped copper layer 110. Or, the lead-free tin layer 120 may be pure tin, tin-copper lead-free solder alloys, tin-silver-copper lead-free solder alloys, or the like formed by other known processes overlaying the tungsten doped copper layer 110. In the present invention, the lead-free tin layer 120 has the tin atoms of at least 95 atom percent, and the thickness of the lead-free tin layer 120 is, depended on applications, ranged between 3 μm and 60 μm.

Furthermore, several examples of the whisker-free coating structure and method for fabricating the same are listed as follows. However, it must note that the materials and processes described in these examples are not intended to limit the scope of the invention. Those skilled in the art will recognize the possibility of using various materials and processes to achieve the described whisker-free coating structure and method for fabricating the same.

### EXAMPLE 1

For introducing one of the examples, an approximately 300 nm thick tungsten doped copper layer 110 having 1.3 atom percent of tungsten is coated overlaying a silicon substrate 100, and then a matte tin layer (i.e., the lead-free tin layer 120) is formed overlaying the tungsten doped copper layer 110 by electroplating with an electric current density of 5 ASD for two minutes. The formed matte tin layer is approximately 3800 nm thick. A surface observation was performed on the surface of the coating (matte tin layer) of the sample immediately after formation of the matte tin layer. No tin whiskers were observed on the sample according to secondary electron images (SEI).

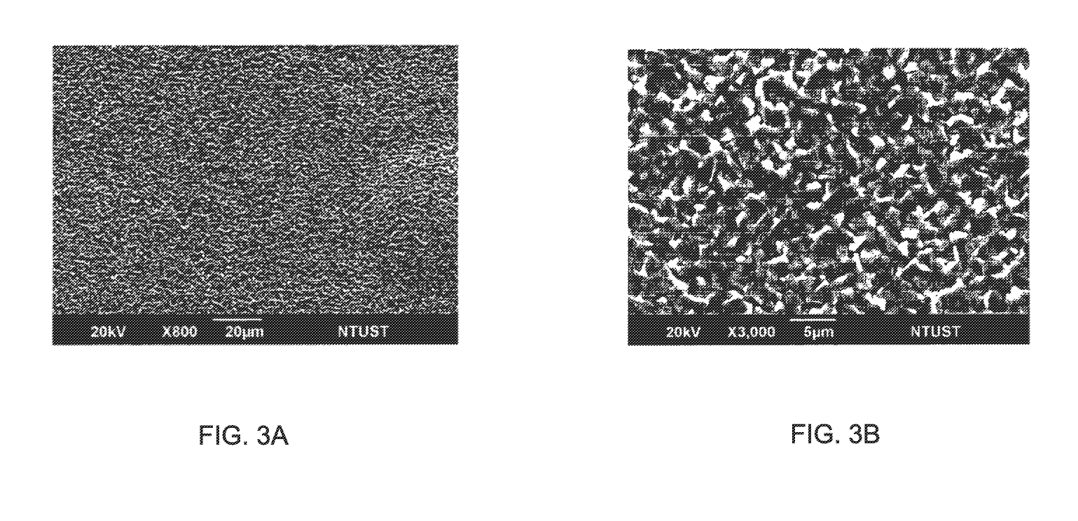

Please refer to FIGS. 3A and 3B, there are shown secondary-electron image photographs of the whisker-free coating structure. For checking the sample of the whisker-free coating structure using the matte tin layer as the lead-free tin layer 120, an accelerated test is performed on the sample. When executing the accelerated test, the sample is disposed under an environmental temperature of 60° C. for 60 hours. Afterward, a surface observation was performed on the surface of the coating (matte tin layer) of the sample immediately after formation of the matte tin layer. No tin whiskers were observed on the sample according to secondary electron images (SEI) as shown in FIGS. 3A and 3B, in which, FIGS. 3A and 3B show images of different zoom-in magnifications. The zoom-in magnifications shown in FIGS. 3A and 3B are set values of the secondary electron image equipment, and not the zoom-in magnifications of the photographs themselves.

### COMPARATIVE EXAMPLE 1

A matte tin layer is formed overlaying a pure copper substrate by electroplating with an electric current density of 5 ASD for two minutes. The formed matte tin layer was approximately 3800 nm thick. A surface observation was performed on the surface of the coating (matte tin layer) of the sample immediately after formation of the matte tin layer. No tin whiskers were observed on the sample according to secondary electron images (SEI).

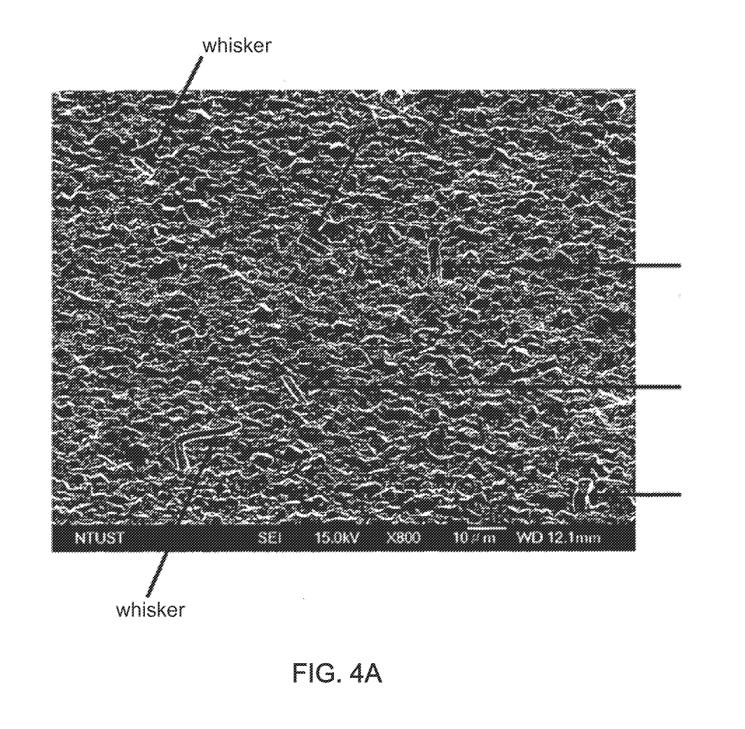

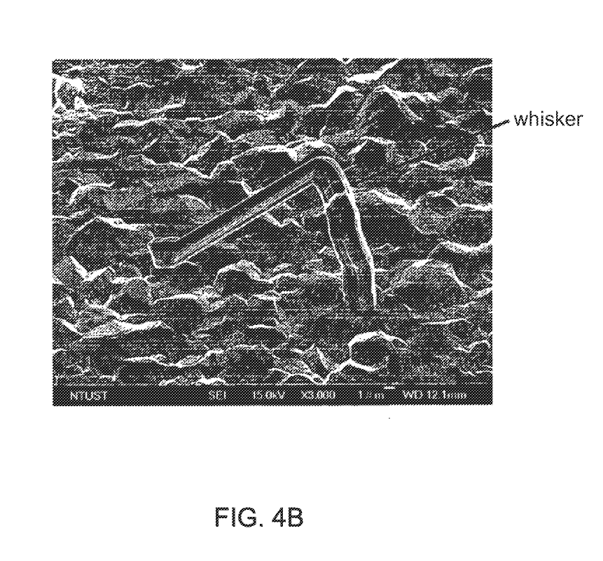

Please refer to FIGS. 4A and 4B, there are shown secondary-electron image photographs of the whisker-free coating structure. Next, an accelerated test was performed on the sample, wherein the sample was disposed under an environmental temperature of 60° C. for 60 hours. Subsequently, a surface observation was performed on the surface of the coating (matte tin layer) of the sample immediately after formation of the matte tin layer. Tin whiskers were observed on the sample according to secondary electron images (SEI) as shown in FIGS. 4A and 4B, wherein the structures indicated by arrow marks are tin whiskers. FIGS. 4A and 4B show images of different zoom-in magnifications. The zoom-in magnifications shown in FIGS. 4A and 4B are set values of the secondary electron image equipment, and not the zoom-in magnifications of the photographs themselves.

Therefore, through above descriptions, the whisker-free coating structure of the present invention have been clearly disclosed and introduced, moreover, the method for fabricating a whisker-free coating structure is also described; In summary, the main advantage of the whisker-free coating structure and the manufacturing method thereof is that the whisker growth in the lead-free tin layers can be effectively suppressed by the whisker-free coating structure of the invention and method for fabricating the same.

The above description is made on embodiments of the present invention. However, the embodiments are not intended to limit scope of the present invention, and all equivalent implementations or alterations within the spirit of the present invention still fall within the scope of the present invention.

We claim:

1. A whisker-free coating structure, comprising:
a substrate;
a tungsten doped copper layer, being formed on the substrate; and
a lead-free tin layer, being formed on the tungsten doped copper layer;
wherein the tungsten doped copper layer has the tungsten atoms of 0.3-8.2 atom percent, and the lead-free tin layer has the tin atoms of at least 95 atom percent.

2. The whisker-free coating structure of claim 1, wherein the tungsten doped copper layer has the tungsten atoms of 0.3-0.6 atom percent.

3. The whisker-free coating structure of claim 1, wherein the substrate is selected from the group consisting of: silicon substrate, copper foil substrate and lead-frame.

4. The whisker-free coating structure of claim 1, wherein the thickness of the tungsten doped copper layer is ranged between 2 and 500 nm.

5. The whisker-free coating structure of claim 1, wherein the material of the lead-free tin layer is selected from the group consisting of: tin, tin-copper alloy and tin-silver-copper alloy.

6. The whisker-free coating structure of claim 1, wherein the lead-free tin layer is a matte tin layer.

7. The whisker-free coating structure of claim 1, wherein the thickness of the lead-free tin layer is ranged between 3 μm and 60 μm.

8. A method for fabricating a whisker-free coating structure, comprising:
providing a substrate;
forming a tungsten doped copper layer on the substrate by way of a vacuum magnetron sputtering apparatus, wherein the tungsten doped copper layer has the tungsten atoms of 0.3-8.2 atom percent; and
forming a lead-free tin layer on the tungsten doped copper layer, wherein the lead-free tin layer has the tin atoms of at least 95 atom percent.

9. The method for fabricating the whisker-free coating structure of claim 8, wherein the lead-free tin layer is formed by electroplating.

10. The method for fabricating the whisker-free coating structure of claim 8, wherein the substrate is selected from the group consisting of: silicon substrate, copper foil substrate and lead-frame.

11. The method for fabricating the whisker-free coating structure of claim 8, wherein the thickness of the tungsten doped copper layer is ranged between 2 and 500 nm.

12. The method for fabricating the whisker-free coating structure of claim 8, wherein the material of the lead-free tin layer is selected from the group consisting of: tin, tin-copper alloy and tin-silver-copper alloy.

13. The method for fabricating the whisker-free coating structure of claim 8, wherein the lead-free tin layer is a matte tin layer.

14. The method for fabricating the whisker-free coating structure of claim 8, wherein the thickness of the lead-free tin layer is ranged between 3 μm and 60 μm.

15. The method for fabricating the whisker-free coating structure of claim 8, wherein the tungsten doped copper layer has the tungsten atoms of 0.3-0.6 atom percent.
